(19) United States
(12) Patent Application Publication
(10) Pub. No.: US 2004/0208035 A1
(43) Pub. Date: Oct. 21, 2004

(54) Data storage device with cable connector that can be securely positioned on a surface of the device

(76) Inventors: Mark Solomon, Cypress, TX (US); Kevin Massaro, Houston, TX (US); Dustin Hoffman, Cypress, TX (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/418,939

(22) Filed: Apr. 18, 2003

(51) Int. Cl. G11C 5/02

(52) U.S. Cl. 365/51

(57) ABSTRACT

A data storage device has a cable that is captive on one end, with a connector housing on the cable that can be securely positioned on a surface of the device. When the connector housing is secured, the device can be inserted into a protective cavity in a host system, and can be electrically attached to an I/O connector within the cavity. When the device is used in an area where its housing might interfere with other devices, the connector housing can be released, and a body of the device can swing freely on the captive end of the cable.

### FIELD OF INVENTION

This invention relates generally to portable data storage devices.

### BACKGROUND

Non-volatile solid-state memory modules are becoming increasingly common for portable data storage. Various forms are used for image storage for digital cameras, for transfer of image data from digital cameras to computers and printers, and for transfer of data between computers and other electronic devices. Some memory modules work only with proprietary connection systems. Other memory modules include interface circuitry to permit connection directly to an industry standard input/output port, for example, USB (Universal Serial Bus). Typically, a USB connector on a portable computer or other portable electronic device is substantially flush with, or only slightly recessed in, a surface of a housing. If a memory module is to be directly connected to a USB connector on a host device, the memory module typically extends out from the housing of the host device, making the memory module susceptible to being accidentally disconnected, or susceptible to damage. For some host devices, a USB connector may be in an area that is crowded with other connectors. If a memory module is to be directly connected (no cable) to a USB connector on a host device in a crowded area, adjacent cable connectors may mechanically interfere with the memory module, or may make connection and removal of the memory module difficult. Some memory modules ship with a short removable cable, so that the cable can be attached to a host device, thereby permitting connection in a crowded area, and the memory module is allowed to swing freely on one end of the removable cable.

### SUMMARY

A data storage device has a cable that is captive on one end, with a connector housing on the cable that can be securely positioned on a surface of the device. When the connector housing is secured, the device can be inserted into a protective cavity in a host system, and can be electrically attached to an I/O connector within the cavity. Alternatively, the connector housing can be released from the body of the device, and the body of the device can swing freely on the captive end of the cable.

### BRIEF DESCRIPTION OF THE DRAWINGS

FIG. 1A is a top view of an example embodiment of a data storage device.

FIG. 1B is an end view of the example data storage device of FIG. 1A.

FIG. 1C is a top view of the example data storage device of FIG. 1A, where an option top is removed, exposing a connector and connector housing, and further illustrating an optional removable memory module.

FIG. 1D is a bottom view of the example data storage device of FIG. 1A.

FIG. 1E is a bottom view of the example data storage device of FIG. 1A, where a captive cable with attached connector has been rotated out of the body of the data storage device.

FIG. 1F is an end view of the example data storage device of FIG. 1A, illustrating a cavity, in the body of the data storage device, into which the connector housing can be securely positioned.

FIG. 1G is an expanded view of a portion of the cavity illustrated in FIG. 1F, further illustrating a locking mechanism.

FIG. 2 is a top view of an alternative example embodiment of a data storage device.

FIG. 3A is a top view of part of a notebook computer with an example embodiment of a cavity for receiving a data storage device.

FIG. 3B is a side view of the notebook computer of FIG. 3A.

FIG. 4 is a top view of an example data storage device as in FIG. 1E or FIG. 2, attached to a host system, with the connector of the data storage device detached from the body of the data storage device.

### DETAILED DESCRIPTION

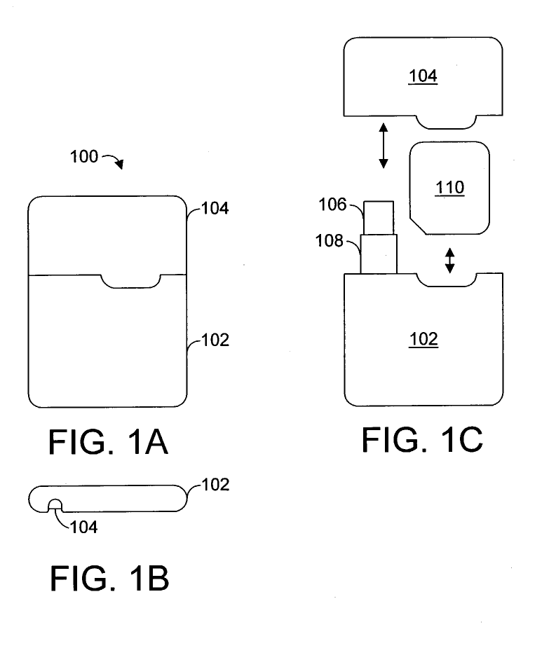

FIG. 1A illustrates a data storage device 100 including a body 102 and an optional protective cap 104. FIG. 1B is an end view illustrating a hinge 104. In FIG. 1C, the cap 104 has been removed, exposing a connector 106 and a connector housing 108. Also illustrated in FIG. 1C is a memory module 110, which optionally may be removable. In FIG. 1C, the memory module is removable through the end covered by the cap.

FIG. 1D illustrates the opposite side of the data storage device of FIG. 1A. A cable 112 is captive to the body of the data storage device through the hinge 104. In FIG. 1E, the hinge and cable have been rotated approximately 180 degrees so that the connector 106 can swing freely on the cable.

FIG. 1F is an end view of the data storage device with the connector detached as illustrated in FIG. 1E, further illustrating a cavity 114, in the body of the data storage device, into which the connector housing 108 resides when the connector housing is secured to the body of the data storage device.

FIG. 1G is an expanded view of one end of the cavity 114, further illustrating a locking mechanism for the connector housing. A flat spring 116 extends into the cavity 114. The spring includes a bump that snaps into a matching indentation (not illustrated) on the connector housing 108 when the connector housing is rotated into the cavity 114. This holds the connector housing securely to the end of the body of the data storage device.

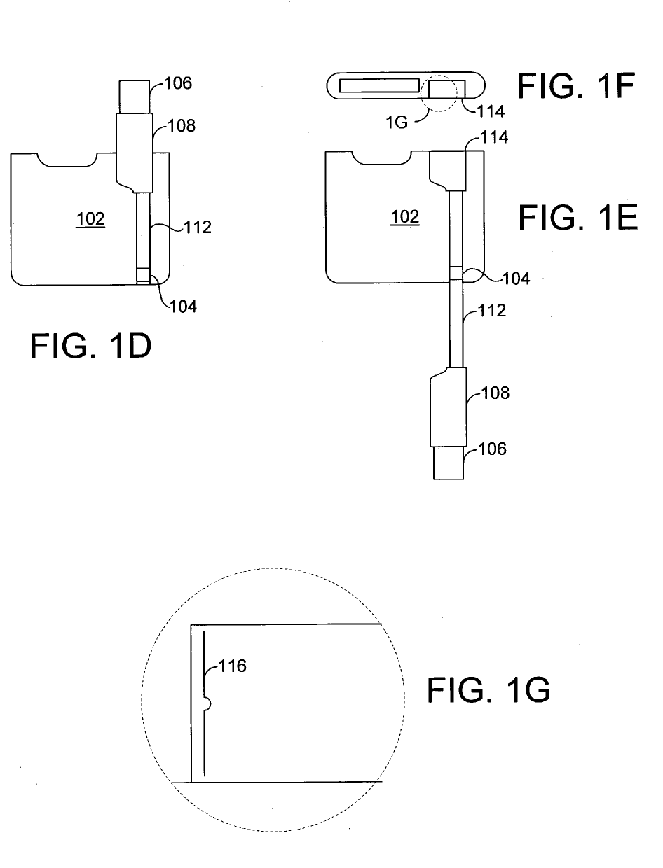

FIG. 2 illustrates an alternative embodiment of a data storage device. In FIG. 2, a data storage device 200 includes a body 202, an optional protective cap 204, a connector 206, a connector housing 208, and a hinged captive cable 210. The cable swings out of one side of the body instead of out the back (as illustrated in FIG. 1E). In the embodiment of FIG. 2, a memory module 212 is optionally removable through an end of the body opposite the end that receives the cap.

The data storage devices may include a fixed data storage module, or a removable data storage module. In FIG. 1C and FIG. 2, a removable flash memory card is used for purposes of illustration. Alternatively, the data storage module may comprise electromechanical memory, such as: a mechanism for rotating media (for example, a magnetic or optical disk drive); a mechanism for translating media (for example, a mechanism for optical cards); or other memory technologies (for example, nanotechnology storage arrays with moving stages).

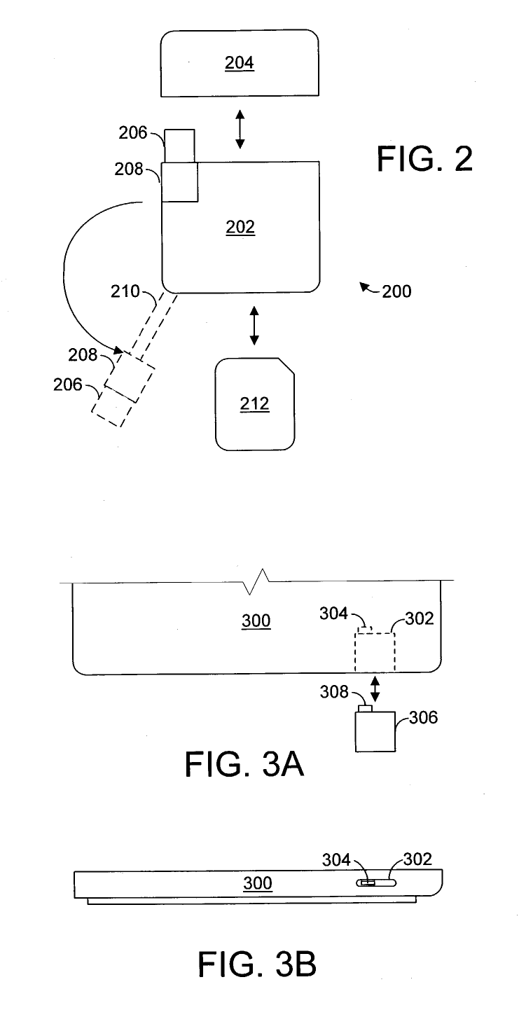

FIG. 3A illustrates an example of a host system with a cavity to receive the data storage device. In FIG. 3A, a notebook computer 300 includes a cavity 302. An I/O connector 304 in the cavity mates with the connector on the data storage device (FIG. 1C, 106; FIG. 2, 206). FIG. 3B is an end view of the notebook computer 300, further illustrating the cavity 302 and I/O connector 304. When the connector on the data storage device is secured to the body of the data storage device, the data storage device may be inserted into a compatible cavity as illustrated in FIGS. 3A and 3B to prevent accidental disconnection or damage.

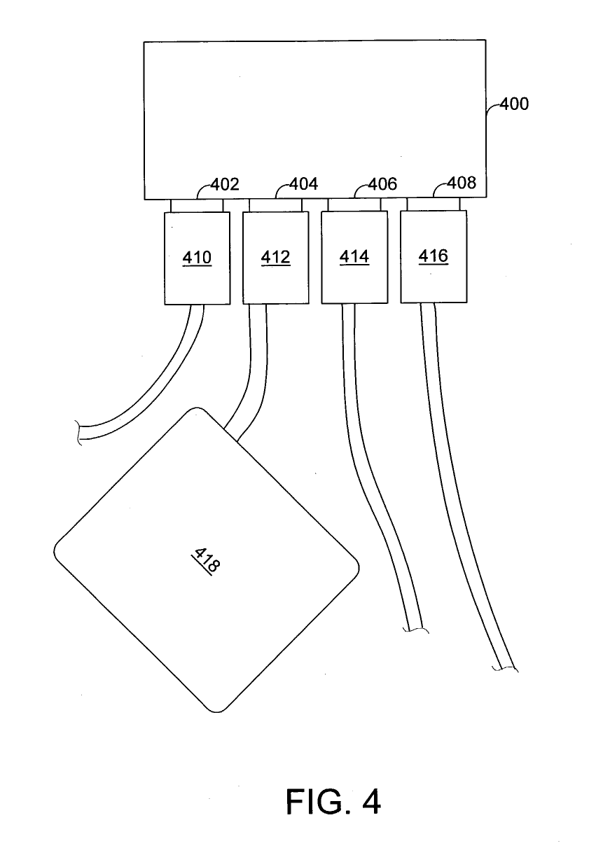

If the data storage device needs to be used in an area where the body of the data storage device might interfere with nearby connectors or other objects, the connector can be detached from the body, as illustrated in FIG. 1E and FIG. 2. FIG. 4 illustrates an example of a host system with a crowded area for attaching I/O cables. The host system 400 includes four I/O connectors 402-408. In FIG. 4, the connector 412 on the data storage device is detached from the body 418 of the data storage device, and connector 412 is attached to I/O connector 404 on the host system.

What is claimed is:

1. A data storage device, comprising:
a body;
an cable having a first end and a second end, the first end attached to the body; and
a connector housing on the second end of the cable, the connector housing being attachable to a surface of the body, and the connector housing being detachable from the surface.

2. The data storage device of claim 1, further comprising a removable memory module.

3. The data storage device of claim 1, further comprising a cap that fits over the connector housing

4. The data storage device of claim 1, further comprising:
an indented area in the body receiving the connector housing.

5. The data storage device of claim 1, further comprising:
a locking mechanism that secures the connector housing to the surface.

6. The data storage device of claim 1, the first end of the cable attached through a hinge mechanism.

7. A method of attaching a data storage device to a host system, comprising:
securing a connector housing on the data storage device to a surface of the data storage device, and inserting the data storage device into a cavity in the host system, when a compatible cavity exists in the host system;
detaching the connector housing from the surface of the data storage device and connecting a connector in the connector housing to an I/O port on the host system, and allowing a body of the data storage device to swing on a cable attached to the connector, when a compatible cavity does not exist in the host system.

8. A data storage device, comprising:
means for securing a connector housing to a surface of the device; and
means for detaching the connector housing so that a body of the device is free to swing on a cable attached to a connector in the connector housing.
